(19) United States
(12) Patent Application Publication
(10) Pub. No.: US 2023/0044481 A1
(43) Pub. Date: Feb. 9, 2023

(54) MUSICAL INSTRUMENT EFFECTS UNIT WITH TRANSISTOR BIAS VOLTAGE VISUALIZATION

(71) Applicant: Charles GIACOMA, Roseville, CA (US)

(72) Inventor: Charles GIACOMA, Roseville, CA (US)

(21) Appl. No.: 17/397,284

(22) Filed: Aug. 9, 2021

(51) Int. Cl. G10H 1/00; H03F 3/183; G10H 1/34; G10H 1/14

(52) U.S. Cl. CPC G10H 1/0008; H03F 3/183; G10H 1/348; G10H 1/14; H03F 2200/03; G10H 2220/005

(57) ABSTRACT

An apparatus and method for providing a musical instrument effects unit with transistor bias voltage visualization are disclosed. An example embodiment includes a musical instrument effects apparatus with transistor bias voltage visualization, the apparatus comprising: a transistor amplifier; a bias control coupled to the transistor amplifier to adjust an active bias voltage setting for the transistor amplifier; and a bias voltage meter coupled to the transistor amplifier to monitor, measure, and enable visualization of the active bias voltage setting, the bias voltage meter including a visualization device to produce a visual representation of the active bias voltage setting.

### COPYRIGHT

A portion of the disclosure of this patent document contains material that is subject to copyright protection. The copyright owner has no objection to the facsimile reproduction of the patent document or the patent disclosure, as it appears in the Patent and Trademark Office patent files or records, but otherwise reserves all copyright rights whatsoever. The following notice applies to the disclosure provided herein and to the drawings that form a part of this document: Copyright 2021 Charles GIACOMA, All Rights Reserved.

### TECHNICAL FIELD

This patent application relates to musical instrument/electric guitar effects pedals, musical instrument effects systems, and musical foot pedals, according to one embodiment, and more specifically to an apparatus and method for providing a musical instrument effects unit or apparatus with transistor bias voltage visualization.

### BACKGROUND

For many years, music effects pedals utilizing germanium transistors to amplify or shape an electrical waveform or sound have been prone to transistor bias voltage drift caused by temperature or power fluctuations. This voltage drift prevents the transistor from operating at its intended bias points to get the desired waveform shape or sound (sweet spot). It has become common practice to include a variable bias voltage control to manipulate the transistor bias into a voltage range that produces the desired waveform or sound; but, this method is inaccurate and difficult when trying to replicate a previously found voltage setting as there is no precise monitor or indicator to clearly show the bias value.

### SUMMARY

In various example embodiments described herein, an apparatus and method for providing a musical instrument effects unit or apparatus with transistor bias voltage visualization are disclosed. In the example embodiments, a musical instrument effects unit solves the problem with conventional effects units by including a readable voltage meter onboard the effects pedal unit to monitor and display the bias voltage of the transistor(s). When used in conjunction with a variable bias control, the user can see in real time where the bias voltage is set and easily adjust for voltage fluctuations to return to the desired setting. This transistor bias voltage visualization provided by the various example embodiments also allows users to adjust the bias knob to find several different tonal settings they prefer and record the displayed voltages to easily return to the desired voltage settings later. The volt meter, or other voltage monitoring and visualization device, can be powered by the same power supply as the effects unit or by an independent power supply or battery. Multiple volt meters can also be employed in one unit to display multiple transistor bias values. The volt meter can be digital or analog. The volt meter, or other voltage monitoring and visualization device, can be mounted and integrated into the effects pedal enclosure in a way that makes the voltage level easily visible to the user. As such, the volt meter, or other voltage monitoring and visualization device, can be integrated with or include a visualization device to produce a visual representation of the active bias voltage setting. Various example embodiments of the musical instrument effects unit with transistor bias voltage visualization are described in detail below.

### BRIEF DESCRIPTION OF THE DRAWINGS

The various embodiments are illustrated by way of example, and not by way of limitation, in the figures of the accompanying drawings in which:

FIG. 1 illustrates an example embodiment including an NPN transistor amplifier with a volume and bias control, a bias voltage meter is also included and referenced to ground and the transistor collector to monitor, measure, and enable visualization of the active bias voltage setting;

FIG. 2 illustrates an example embodiment including a PNP transistor amplifier with a volume and bias control, a bias voltage meter is also included and referenced to positive ground and the transistor collector to monitor, measure, and enable visualization of the active bias voltage setting;

FIG. 3 illustrates an example embodiment including a PNP transistor amplifier with a volume and bias control, a bias voltage meter is also included and referenced to positive ground and the transistor base to monitor, measure, and enable visualization of the active bias voltage setting;

FIG. 4 illustrates an example embodiment of a “Fuzz” effect circuit including an integrated bias voltage meter to monitor, measure, and enable visualization of the active bias voltage setting;

FIG. 5 illustrates an example embodiment of a “Fuzz” effect circuit including a plurality of integrated bias voltage meters to monitor, measure, and enable visualization of the active bias voltage setting at a plurality of stages or locations in the circuit;

FIG. 6 illustrates an example embodiment of a “Fuzz” effect pedal having an integrated “Fuzz” effect circuit with a bias voltage meter to monitor, measure, and enable visualization of the active bias voltage setting of the circuit, the visualization in the illustrated example showing an active bias voltage setting indicating a non-ideal voltage;

FIG. 7 illustrates an example embodiment of a “Fuzz” effect pedal having an integrated “Fuzz” effect circuit with a bias voltage meter to monitor, measure, and enable visualization of the active bias voltage setting of the circuit, the visualization in the illustrated example showing an active bias voltage setting indicating an ideal or desired voltage; and

FIG. 8 illustrates a flow diagram that shows an example embodiment of a method as described herein.

### DETAILED DESCRIPTION

In the following description, for purposes of explanation, numerous specific details are set forth in order to provide a thorough understanding of the various embodiments. It will be evident, however, to one of ordinary skill in the art that the various embodiments may be practiced without these specific details.

In various example embodiments described herein, an apparatus and method for providing a musical instrument effects unit or apparatus with transistor bias voltage visualization are disclosed. In the example embodiments, a musical instrument effects unit solves the problem with conventional effects units by including a readable voltage meter onboard the effects pedal unit to monitor and display the bias voltage of the transistor(s). When used in conjunction with a variable bias control, the user can see in real time where the bias voltage is set and easily adjust for voltage fluctuations to return to the desired setting. This transistor bias voltage visualization provided by the various example embodiments also allows users to adjust the bias knob to find several different tonal settings they prefer and record the displayed voltages to easily return to the desired voltage settings later. The volt meter, or other voltage monitoring and visualization device, can be powered by the same power supply as the effects unit or by an independent power supply or battery. Multiple volt meters can also be employed in one unit to display multiple transistor bias values. The volt meter can be digital or analog. The volt meter, or other voltage monitoring and visualization device, can be mounted and integrated into the effects pedal enclosure in a way that makes the voltage level easily visible to the user. As such, the volt meter, or other voltage monitoring and visualization device, can be integrated with or include a visualization device to produce a visual representation of the active bias voltage setting.

In one example embodiment, the musical instrument effects unit with transistor bias voltage visualization can be used with or for Germanium transistor based “fuzz” effects pedals. Germanium transistors, which themselves are well-known to those of ordinary skill in the art, have a very narrow bias sweet spot and operate best when center biased (e.g., if the supply voltage is 9 volts, the ideal bias would be 4.5 volts at the transistor collector.) These Germanium transistors drastically fluctuate bias in different environmental temperatures. For example, if a Germanium transistor is set for 4.5 volts at 70 degrees Fahrenheit room temperature, the Germanium transistor could swing+/−3 volts with a 30 degree environmental temperature change. Given the conventional systems lack of bias voltage monitoring and visualization, the conventional systems cannot enable a user to identify and adjust for these environmental temperature changes. In contrast to the conventional systems, the musical instrument effects unit with transistor bias voltage visualization of the example embodiments as disclosed herein provides an onboard or integrated bias voltage meter to allow the user to quickly and accurately monitor, view, and adjust the bias voltage back to a desired setting in the event of environmental temperature changes or other conditions affecting the bias voltage.

In other example embodiments, the musical instrument effects unit with transistor bias voltage visualization can be used with or for other types of transistors or transistor circuits that may not fluctuate (or may not fluctuate as much) with temperature or other environmental or operational conditions. For example, silicon transistors provide the ability for a user to easily and accurately identify bias voltages that produce desirable results. However, small changes in the bias control voltage may produce wildly different sounds. As such, it is important for a user to be able to accurately and precisely set the bias control voltage to produce a desired result. Moreover, it is important to enable the user to reproduce a desired result by precisely setting the bias control voltage corresponding to the desired result. Unlike conventional effects units, the musical instrument effects unit with transistor bias voltage visualization as disclosed herein enables a user to monitor, view, and precisely set and reproduce the bias control voltage to produce a desired result.

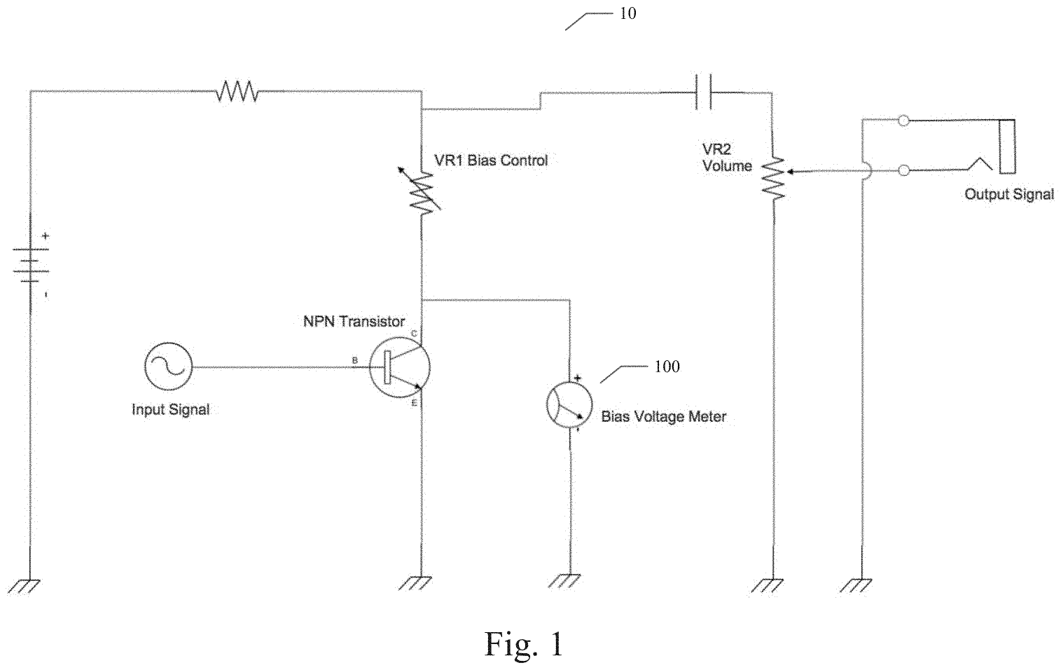

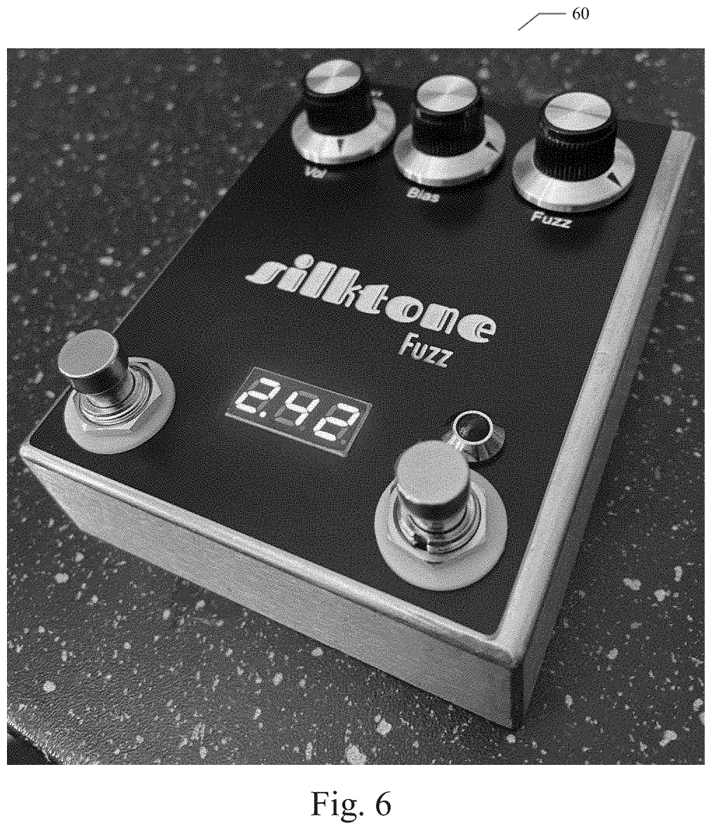

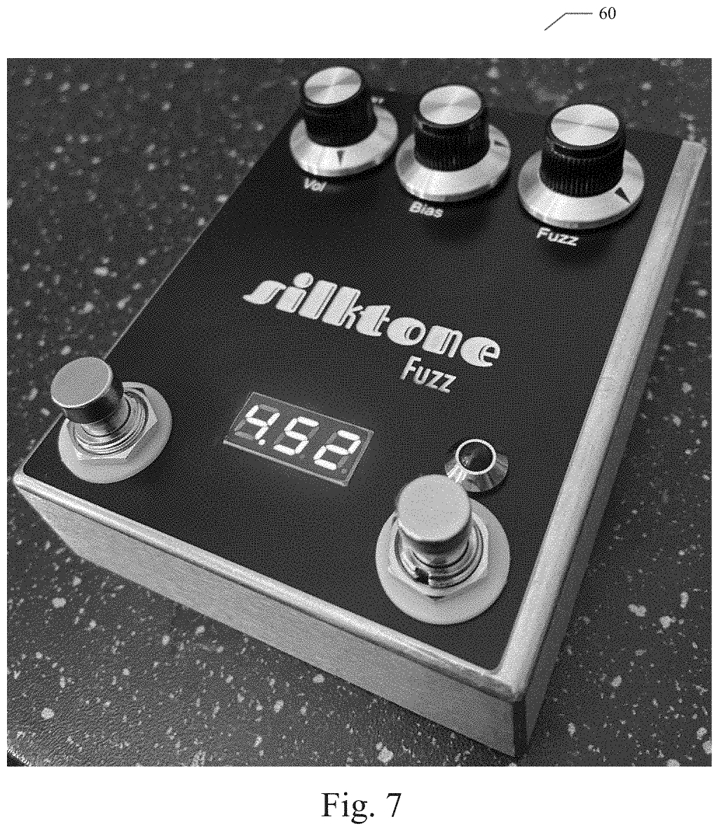

Referring now to FIG. 1, an example embodiment of a circuit 10 for a musical instrument effects unit with transistor bias voltage visualization is illustrated. In particular, FIG. 1 illustrates an example embodiment of circuit 10 including an NPN transistor amplifier with a volume and bias control; a bias voltage meter 100 is also included and referenced to ground and the transistor collector to monitor, measure, and enable visualization of the active bias voltage setting. In the example embodiment of circuit 10, the bias voltage meter 100 shares a power supply with the effect circuit. Using known techniques, the bias voltage meter 100 can be coupled to or integrated with a conventional visualization device, such as a digital numeric display (e.g., see FIGS. 6 and 7), an LED or LCD readout, an analog gauge with a moving needle or slide bar, a color-coded indicator, or other device for presenting a voltage level visualization to a user. The integration of the bias voltage meter 100 into circuit 10 enables the musical instrument effects unit with transistor bias voltage visualization of the example embodiments as disclosed herein to allow the user to quickly and accurately monitor, view, and adjust the bias voltage to (or back to) a desired setting in the event of environmental temperature changes or other conditions affecting the bias voltage.

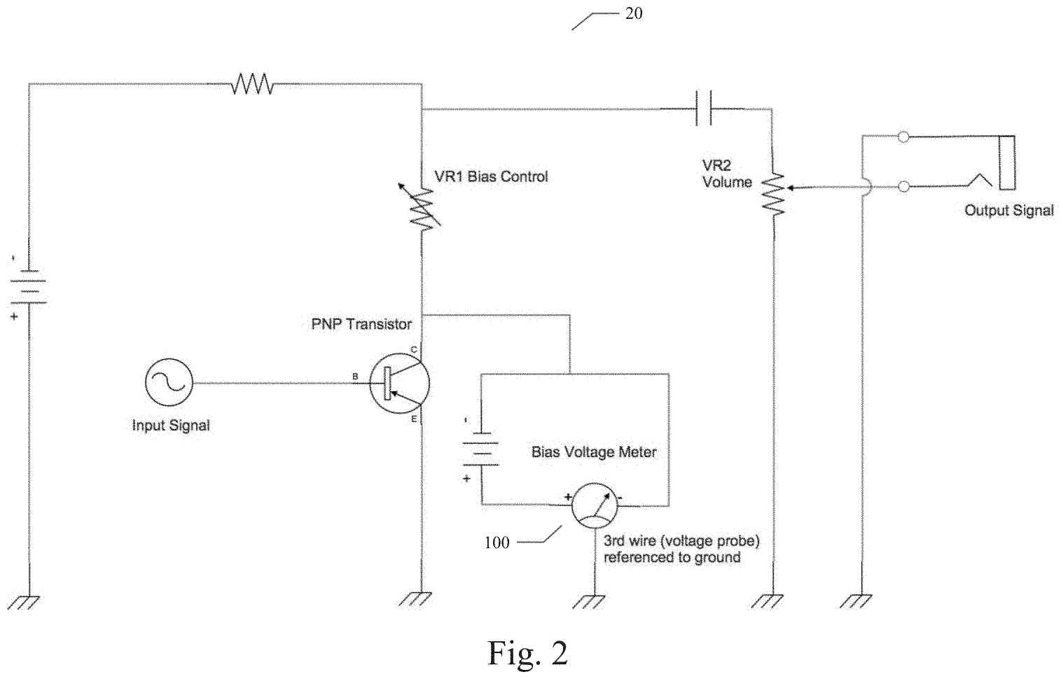

Referring now to FIG. 2, an example embodiment of a circuit 20 for a musical instrument effects unit with transistor bias voltage visualization is illustrated. In particular, FIG. 2 illustrates an example embodiment of circuit 20 including a PNP transistor amplifier with a volume and bias control; a bias voltage meter 100 is also included and referenced to positive ground and the transistor collector to monitor, measure, and enable visualization of the active bias voltage setting. In the example embodiment of circuit 20, the bias voltage meter 100 is independently powered. As described above, the bias voltage meter 100 can be coupled to or integrated with a conventional visualization device, such as a digital numeric display (e.g., see FIGS. 6 and 7), an LED or LCD readout, an analog gauge with a moving needle or slide bar, a color-coded indicator, or other device for presenting a voltage level visualization to a user. The integration of the bias voltage meter 100 into circuit 20 enables the musical instrument effects unit with transistor bias voltage visualization of the example embodiments as disclosed herein to allow the user to quickly and accurately monitor, view, and adjust the bias voltage to (or back to) a desired setting in the event of environmental temperature changes or other conditions affecting the bias voltage.

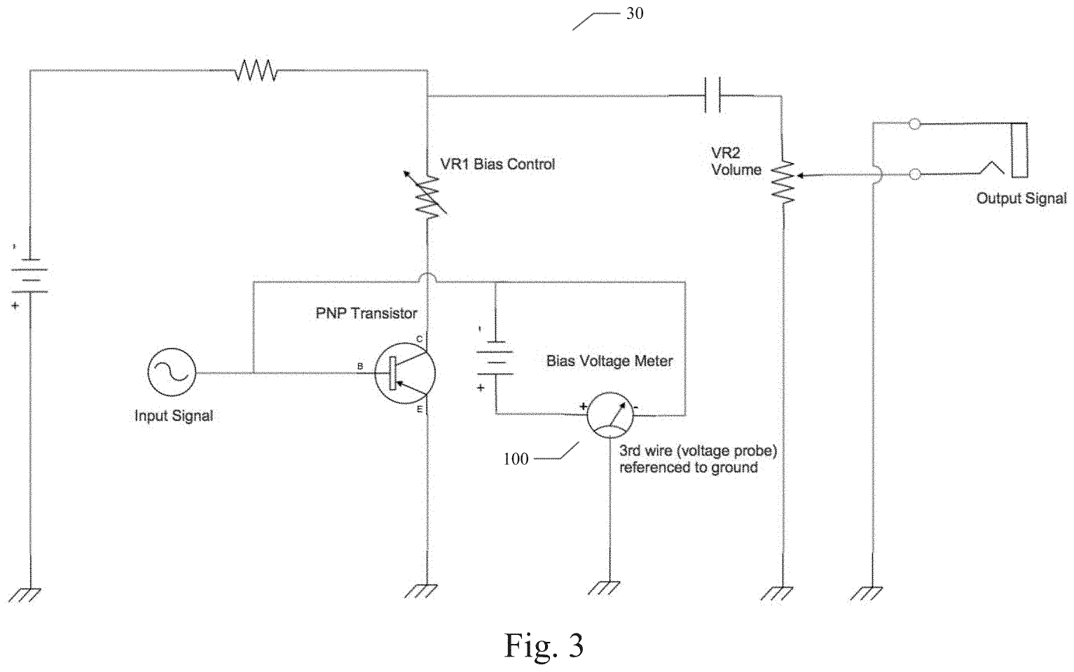

Referring now to FIG. 3, an example embodiment of a circuit 30 for a musical instrument effects unit with transistor bias voltage visualization is illustrated. In particular, FIG. 3 illustrates an example embodiment of circuit 30 including a PNP transistor amplifier with a volume and bias control; a bias voltage meter 100 is also included and referenced to positive ground and the transistor base to monitor, measure, and enable visualization of the active bias voltage setting. In the example embodiment of circuit 30, the bias voltage meter 100 is independently powered. As described above, the bias voltage meter 100 can be coupled to or integrated with a conventional visualization device, such as a digital numeric display (e.g., see FIGS. 6 and 7), an LED or LCD readout, an analog gauge with a moving needle or slide bar, a color-coded indicator, or other device for presenting a voltage level visualization to a user. The integration of the bias voltage meter 100 into circuit 30 enables the musical instrument effects unit with transistor bias voltage visualization of the example embodiments as disclosed herein to allow the user to quickly and accurately monitor, view, and adjust the bias voltage to (or back to) a desired setting in the event of environmental temperature changes or other conditions affecting the bias voltage.

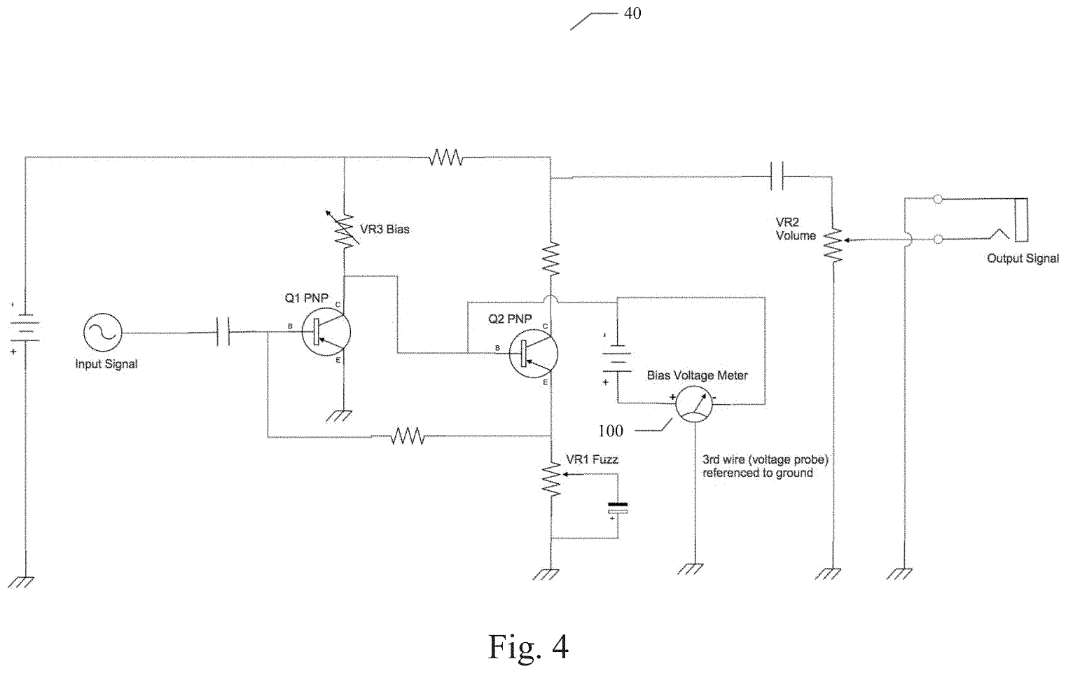

Referring now to FIG. 4, an example embodiment of a circuit 40 for a musical instrument effects unit with transistor bias voltage visualization is illustrated. In particular, FIG. 4 illustrates an example embodiment of a “Fuzz” effect circuit 40 including an integrated bias voltage meter 100 to monitor, measure, and enable visualization of the active bias voltage setting. The example embodiment of circuit 40 is a two transistor amplifier with a volume and fuzz control with the addition of a bias control. In the example embodiment of circuit 40, the bias voltage meter 100 is referenced to positive ground and the shared Q1 transistor collector/Q2 transistor base to monitor, measure, and enable visualization of the active bias voltage setting. In the example embodiment of circuit 40, the bias voltage meter 100 is independently powered. As described above, the bias voltage meter 100 can be coupled to or integrated with a conventional visualization device, such as a digital numeric display (e.g., see FIGS. 6 and 7), an LED or LCD readout, an analog gauge with a moving needle or slide bar, a color-coded indicator, or other device for presenting a voltage level visualization to a user. The integration of the bias voltage meter 100 into circuit 40 enables the musical instrument effects unit with transistor bias voltage visualization of the example embodiments as disclosed herein to allow the user to quickly and accurately monitor, view, and adjust the bias voltage to (or back to) a desired setting in the event of environmental temperature changes or other conditions affecting the bias voltage.

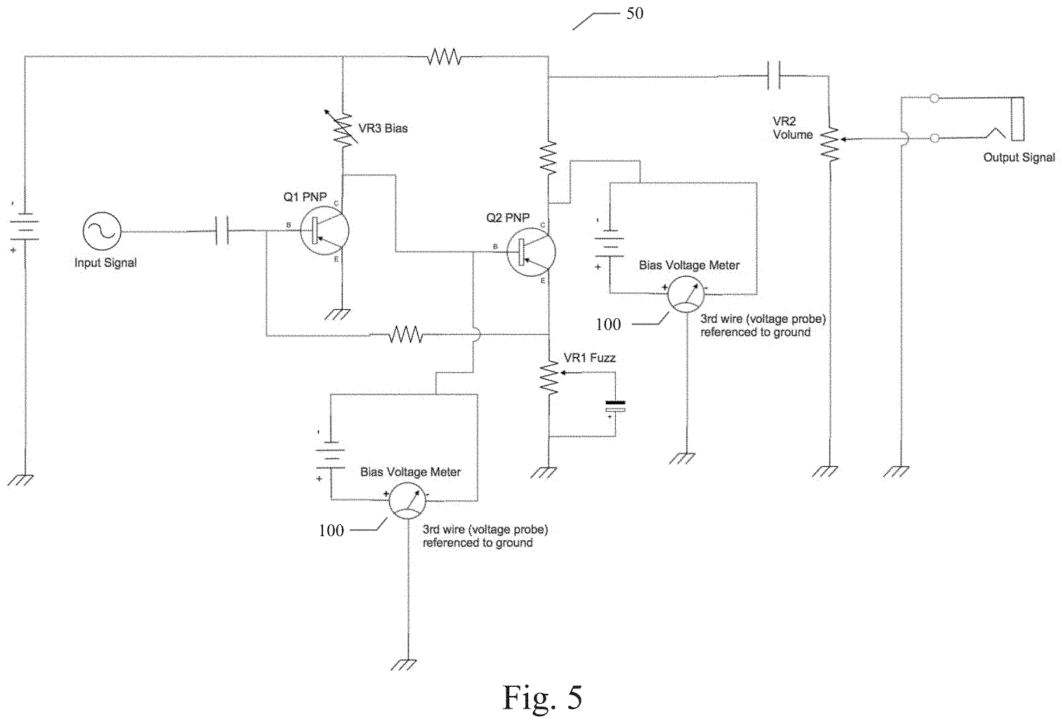

Referring now to FIG. 5, an example embodiment of a circuit 50 for a musical instrument effects unit with transistor bias voltage visualization is illustrated. In particular, FIG. 5 illustrates an example embodiment of a “Fuzz” effect circuit 50 including a plurality of integrated bias voltage meters 100 to monitor, measure, and enable visualization of the active bias voltage setting at a plurality of stages or locations in the circuit 50. The example embodiment of circuit 50 is a two transistor amplifier with a volume and fuzz control with the addition of a bias control. A first bias voltage meter 100 is referenced to positive ground and the shared Q1 transistor collector/Q2 transistor base to monitor, measure, and enable visualization of the active bias voltage setting at a first stage or first location of circuit 50 corresponding to a first transistor (e.g., the Q1 transistor in the illustrated example). As also shown in FIG. 5, a second bias voltage meter 100 is referenced to positive ground and the Q2 transistor collector to monitor, measure, and enable visualization of the active bias voltage setting at a second stage or second location of circuit 50 corresponding to a second transistor (e.g., the Q2 transistor in the illustrated example). In the example embodiment of circuit 50, the bias voltage meters 100 are independently powered. The use of a plurality of integrated bias voltage meters 100 in circuit 50 enables monitoring and visualization of the active bias voltage setting at a plurality of stages or locations in circuit 50. This allows a user to monitor and view a plurality of independent bias voltage settings, which allows access to recording settings for a wider variety of tones produced by the changing bias voltage settings of a plurality of transistors within circuit 50.

FIG. 6 illustrates an example embodiment of a “Fuzz” effect pedal 60 having an integrated “Fuzz” effect circuit, such as circuit 40 described above, with a bias voltage meter 100 to monitor, measure, and enable visualization of the active bias voltage setting of the circuit. As shown in FIG. 6, the bias voltage meter 100 can be coupled to or integrated with a conventional visualization device, such as a digital numeric display for presenting a voltage level visualization to a user. In the example of FIG. 6, the visualization of the bias voltage level in the illustrated example shows an active bias voltage setting indicating a non-ideal voltage. Because of the voltage level visualization provided by the example embodiments disclosed herein, the user can readily see that the active bias voltage setting needs to be adjusted.

FIG. 7 illustrates an example embodiment of the “Fuzz” effect pedal 60 having an integrated “Fuzz” effect circuit, such as circuit 40 described above, with a bias voltage meter 100 to monitor, measure, and enable visualization of the active bias voltage setting of the circuit. FIGS. 6 and 7 depict a visual example of the enclosure or housing of the musical instrument effects unit disclosed herein and the bias voltage meter 100 visualization in use. Because of the voltage level visualization provided by the example embodiments disclosed herein, the user can readily see the active bias voltage setting of the circuit and adjust the voltage level accordingly. In the example of FIG. 7, the user has used the visualization of the active bias voltage setting provided by the example embodiments disclosed herein to adjust the active bias voltage setting to an ideal or desired voltage.

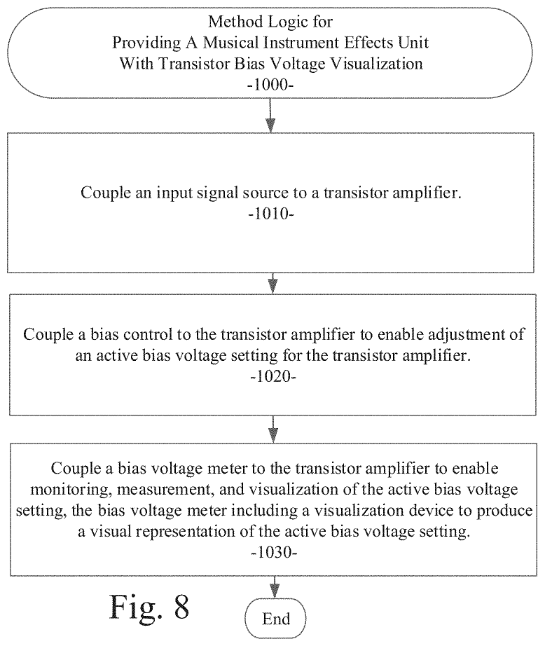

Referring now to FIG. 8, a flow diagram illustrates an example embodiment of a method implemented by the apparatus and systems as described herein. The method 1000 of an example embodiment includes: coupling an input signal source to a transistor amplifier (block 1010); coupling a bias control to the transistor amplifier to enable adjustment of an active bias voltage setting for the transistor amplifier (block 1020); and coupling a bias voltage meter to the transistor amplifier to enable monitoring, measurement, and visualization of the active bias voltage setting, the bias voltage meter including a visualization device to produce a visual representation of the active bias voltage setting (block 1030).

Thus, in various example embodiments described herein, an apparatus and method for providing a musical instrument effects unit with transistor bias voltage visualization are disclosed. As described above in connection with the figures provided herewith, a musical instrument effects unit with transistor bias voltage visualization can be implemented in or with a variety of different circuits. In the various example embodiments disclosed herein, the addition and integration of a voltage meter, or other voltage monitoring and visualization device used as a bias voltage monitor in various musical instrument effects circuits, enables monitoring and visualization of one or more active bias voltage settings within the musical instrument effects circuit. This is a new idea and an improvement on conventional music effects pedals and related circuits. The improvements provided by the various example embodiments disclosed herein enable a user to more easily, quickly, and precisely find and replicate desirable tones with a music effects pedal.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A musical instrument effects apparatus with transistor bias voltage visualization, the apparatus comprising:
a transistor amplifier;
a bias control coupled to the transistor amplifier to adjust an active bias voltage setting for the transistor amplifier; and
a bias voltage meter coupled to the transistor amplifier to monitor, measure, and enable visualization of the active bias voltage setting, the bias voltage meter including a visualization device to produce a visual representation of the active bias voltage setting.

2. The apparatus of claim 1 wherein the transistor amplifier is of a type from a group consisting of: an NPN transistor amplifier, and a PNP transistor amplifier.

3. The apparatus of claim 1 wherein the transistor amplifier is of a type from a group consisting of: a Germanium transistor, and a silicon transistor.

4. The apparatus of claim 1 wherein the bias control is a variable bias control coupled to a collector of the transistor amplifier.

5. The apparatus of claim 1 wherein the bias voltage meter is coupled to a collector of the transistor amplifier.

6. The apparatus of claim 1 wherein the bias voltage meter is coupled to a base of the transistor amplifier.

7. The apparatus of claim 1 wherein the bias voltage meter shares a power supply with the transistor amplifier.

8. The apparatus of claim 1 wherein the bias voltage meter is powered independently of the transistor amplifier.

9. The apparatus of claim 1 including a “Fuzz” effect circuit.

10. The apparatus of claim 1 including a plurality of transistor amplifiers and a plurality of bias voltage meters.

11. The apparatus of claim 1 wherein the visualization device is of a type from a group consisting of: a digital numeric display, an LED readout, an LCD readout, an analog gauge, an analog gauge with a moving needle, an analog gauge with a slide bar, a color-coded indicator, and a device for presenting a voltage level visualization to a user.

12. The apparatus of claim 1 wherein the transistor amplifier, the bias control, and the bias voltage meter are integrated into a musical instrument effects pedal, the voltage level visualization being visible externally to the musical instrument effects pedal.

13. A method for transistor bias voltage visualization, the method comprising:
coupling an input signal source to a transistor amplifier;
coupling a bias control to the transistor amplifier to enable adjustment of an active bias voltage setting for the transistor amplifier; and
coupling a bias voltage meter to the transistor amplifier to enable monitoring, measurement, and visualization of the active bias voltage setting, the bias voltage meter including a visualization device to produce a visual representation of the active bias voltage setting.

14. The method of claim 13 wherein the transistor amplifier is of a type from a group consisting of: an NPN transistor amplifier, and a PNP transistor amplifier.

15. The method of claim 13 wherein the bias control is a variable bias control coupled to a collector of the transistor amplifier.

16. The method of claim 13 wherein the bias voltage meter is coupled to a collector of the transistor amplifier.

17. The method of claim 13 wherein the bias voltage meter is powered independently of the transistor amplifier.

18. The method of claim 13 including coupling a plurality of bias voltage meters to a plurality of transistor amplifiers.

19. The method of claim 13 wherein the visualization device is of a type from a group consisting of: a digital numeric display, an LED readout, an LCD readout, an analog gauge, an analog gauge with a moving needle, an analog gauge with a slide bar, a color-coded indicator, and a device for presenting a voltage level visualization to a user.

20. The method of claim 13 including integrating the transistor amplifier, the bias control, and the bias voltage meter into a musical instrument effects pedal, the voltage level visualization being visible externally to the musical instrument effects pedal.
